(19) United States
(12) Patent Application Publication
(10) Pub. No.: US 2013/0113366 A1
(43) Pub. Date: May 9, 2013

(54) COLOR CONTROL OF SOLID STATE LIGHT SOURCES

(71) Applicants: Deeder Aurongzeb, Mayfield Heights, OH (US); Juliana P. Reisman, Beachwood, OH (US)

(72) Inventors: Deeder Aurongzeb, Mayfield Heights, OH (US); Juliana P. Reisman, Beachwood, OH (US)

(21) Appl. No.: 13/291,001

(22) Filed: Nov. 7, 2011

(51) Int. Cl. H05B 33/02; C23C 14/34; B05D 5/06; H01J 5/16

(52) U.S. Cl. 313/504; 313/112; 427/523; 427/66

(57) ABSTRACT

Disclosed herein are systems and method for controlling color of solid state light sources, such as OLEDs. Included here is an illumination system comprising a solid state light source optically coupled with a selectively absorbing brightness enhancing layer. Also disclosed herein are methods for making a selectively absorbing brightness enhancing film. Disclosed advantages may include adjustment of the color of a solid state light source which has undergone color shift due degradation.

### FIELD OF THE INVENTION

The present invention relates generally to solid state light sources, and more particularly, the present invention generally relates to color control and brightness enhancement of solid state light sources.

### BACKGROUND

Solid state light sources, such as organic light emitting diode devices, or OLED devices, are generally known in the art. These solid state light sources are increasingly sought for their long life, durability, and energy efficiency. As is generally known, many known OLED devices typically include one or more organic light emitting layer(s) disposed between electrodes. For example, first and second electrodes, such as a cathode and a light transmissive anode are formed on a substrate. Light is emitted when current is applied across the cathode and anode. As a result of the electric current, electrons are injected into the organic layer from the cathode and holes may be injected into the organic layer from the anode. Electrons and holes generally travel through the organic layer until they recombine at a luminescent center, typically an organic molecule or polymer. The recombination process results in the emission of a light photon usually in the visible region of the electromagnetic spectrum.

The layers of an OLED are typically arranged so that the organic layers are disposed between the cathode and anode layers. As photons of light are generated and emitted, the photons move through the organic layer. Those that move toward the cathode, which generally comprises a metal, may be reflected back into the organic layer. Those photons that move through the organic layer to the light transmissive anode, and finally to the substrate, may be emitted from the OLED in the form of light energy. Light transmissive anodes have been composed of substantially transparent nonmetallic conductive materials, such as indium tin oxide. Of course, additional, optional layers may or may not be included in the light source structure.

For many purposes, one may desire solid state light sources such as OLED devices to be generally flexible, e.g., are capable of being bent into a shape having a radius of curvature of less than about 10 cm. These light sources are also preferably large-area, which means they have a dimension of an area greater than or equal to about 10 cm², and in some instances are coupled together to form a generally flexible, generally planar OLED panel comprised of one or more OLED devices, which has a large surface area of light emission. Currently, many such OLED devices need to be hermetically sealed since moisture and oxygen may have an adverse impact on the OLED device.

However, optical performance of OLED devices may sometimes be limited by the difficulties associated with light extraction from large planar surfaces of moderate optical refractive index into the ambient environment. For example, if an OLED material has a high refractive index, only a low fraction of light may be extracted into ambient air. There can be losses from internal reflection at the air interface, edge emission, dissipation within the emissive or other layers, waveguide effects within the emissive layer or other layers of the device (i.e., transporting layers, injection layers, etc.), and other effects. While thicker devices can sometime ameliorate these losses, this tends to lead to power efficiency losses as the active layers of the OLED are increased in thickness. In the absence of corrective techniques, only a fraction of the light generated within the device is actually emitted into the ambient environment, due to these and other deleterious phenomena.

Therefore, many schemes have been proposed to increase the light output from OLED devices, some involve texturing or patterning one or more interfaces or layers within or external to the OLED. Patterning a substrate allows for light that has been trapped in the substrate to be extracted, and increase the total light extraction. It has also been sometimes proposed to affix outcoupling films (OCF) to extract light from the OLED. Often, the use of an OCF in an OLED can potentially increase lumen per watt (LPW) significantly, e.g., from 25 to 35. Outcoupling films, also known as brightness enhancing films (BEF), function at least in part by directing or turning light from an illumination source toward a viewer, thus making the source appear brighter and/or economizing on power consumption.

Despite the effectiveness of conventional outcoupling films, however, and in view of the persistent concerns noted above, there remains a need to develop improved means of extracting light generated by solid state light sources such as OLEDs.

### BRIEF SUMMARY

One embodiment of the present invention is directed to an illumination system comprising a solid state light source optically coupled with a selectively absorbing brightness enhancing layer.

A further embodiment of the present invention is directed to an illumination system comprising an encapsulated, flexible, conformal solid state white light source comprising one or more organic electroluminescent device and at least one barrier layer. The illumination system further comprises at least one selectively absorbing brightness enhancing film which is external to the encapsulated white light source. The selectively absorbing brightness enhancing film is capable of modifying at least one of chromaticity, color contrast, or color temperature of light emitted from the white light source.

An even further embodiment of the present invention is directed to a method comprising optically coupling a solid state light source with a selectively absorbing brightness enhancing layer.

A yet further embodiment of the present invention is directed to a method of changing the chromaticity of a flexible organic electroluminescent white light source. The method comprises optically coupling a selectively absorbing brightness enhancing film and a flexible organic electroluminescent white light source.

An even further embodiment of the present invention is directed to a method of making a selectively absorbing brightness enhancing film, which comprises at least a step of doping a film with a selectively absorbing material.

Other features and advantages of this invention will be better appreciated from the following detailed description.

### BRIEF DESCRIPTION OF THE DRAWINGS

Embodiments of the invention will now be described in greater detail with reference to the accompanying Figures.

FIG. 1 is a schematic depiction of a first illumination system according to embodiments of the disclosure.

FIG. 2 is a schematic depiction of a second illumination system according to embodiments of the disclosure.

FIG. 3 is a schematic depiction of a third illumination system according to embodiments of the disclosure.

FIG. 4 is a schematic illustration of an illumination system comprising an encapsulated OLED light source and a selectively absorbing brightness enhancing layer according to embodiments of the disclosure.

FIG. 5 shows spectral plots of an illumination system with and without a selectively absorbing brightness enhancing layer.

### DETAILED DESCRIPTION

As noted, an embodiment of the present invention is directed to an illumination system comprising a solid state light source optically coupled with a selectively absorbing brightness enhancing layer. In general, such solid state light source is configured to emit light, when energized, comprising a first color temperature, a first chromaticity, and a first color contrast parameter; and the selectively absorbing brightness enhancing layer may typically be chosen to be capable of modifying at least one of the first color temperature, the first chromaticity, or the first color contrast parameter of the solid state light source. In some embodiments, such selectively absorbing brightness enhancing layer may be capable of modifying all of first color temperature, the first chromaticity, and the first color contrast parameter of the solid state light source.

For example, the selectively absorbing brightness enhancing layer may be capable of increasing the color temperature of the light emitted from a solid state light source by at least about 50 K (preferably, by at least about 200 K, e.g., from about 50 to about 400 K increase). In certain embodiments, the selectively absorbing brightness enhancing layer may be capable of decreasing a dCCY of the light emitted from the solid state light source. In other embodiments, the selectively absorbing brightness enhancing layer may be capable of increasing red-green color contrast of light emitted from the solid state light source. In yet other embodiments, the selectively absorbing brightness enhancing layer may be capable of imparting color contrast values to the light emitted by the solid state light source, which values conform to the CQS (NIST Color Quality System) parameters set forth in Paragraphs [0039], [0040], or [0041] of US Patent Publication 2009/0122530, which is hereby incorporated by reference in its entirety as if set forth fully herein.

As used herein, the terms “illumination system” and “lamp” will be utilized substantially interchangeably, to refer to any source of visible light which can be generated by at least one solid-state light-emitting source. As used herein, the term “solid-state light source” typically may include an inorganic light emitting diode (e.g., LED), an organic electroluminescent device (e.g. OLED), an inorganic electroluminescent device, a laser diode, or combinations thereof; or the like. In some embodiments, the solid state light source may comprise at least one organic electroluminescent light emitting device, at least one inorganic light emitting device, or combinations thereof. In some embodiments, the solid state light source may comprise a plurality of organic electroluminescent light emitting devices, a plurality of inorganic light emitting devices, or combinations thereof. In accordance with certain embodiments of the disclosure, the solid state light source may be conformal; that is, it may be formed into the shape of an underlying structure or substrate (e.g., cast in shaped form). It may also be flexible as well as conformal, wherein flexible typically may refer to the capability of being bent into a shape having a radius of curvature of less than about 10 cm.

As used herein, the term “light emitting diode” or “LED” may include a laser diode, a resonant cavity LED, superluminescent LED, flip chip LED, vertical cavity surface emitting laser, high-brightness LED or other diodic lighting device as would be understood by a person skilled in the field. Suitable light emitting diodes may comprise one or more of an inorganic nitride, carbide, or phosphide. The person of skill in the art is familiar with the wide array of commercially available LEDs and their composition and construction is well understood. In particular, as used herein, the term “inorganic light emitting diode” generally refers to those light emitting diodes where the p-n junction is predominantly constructed from inorganic materials. The term “inorganic light emitting diode” does not preclude the presence of non-inorganic materials elsewhere in a device.

As is generally understood, an organic electroluminescent device typically includes one or more organic light emitting layers disposed between electrodes, e.g., a cathode and a light transmissive anode, formed on a substrate, often a light-transmissive substrate. The light-emitting layer emits light upon application of a current across the anode and cathode. Upon the application of an electric current, electrons may be injected into the organic layer from the cathode, and holes may be injected into the organic layer from the anode. The electrons and the holes generally travel through the organic layer until they recombine at a luminescent center, typically an organic molecule or polymer, which recombination process results in the emission of a light photon, which usually can be in the ultraviolet or visible regions of the spectrum. As used herein, the term “organic electroluminescent device” generally refers to a device (e.g., including electrodes and active layer) comprising an active layer having an organic material (molecule or polymer) which exhibits the characteristic of electroluminescence. An OLED device does not preclude the presence of inorganic materials. If it is specified that more than one “organic electroluminescent device” is present, the organic material may be the same (e.g., where multiple layers of the same material are arranged), or may be different (e.g., where multiple layers of different materials are arranged). Furthermore, different kinds of organic electroluminescent materials can be present (e.g., mixed) in the same layer.

As will be appreciated by one skilled in the art, an organic electroluminescent device may include additional layers such as hole transport layers, hole injection layers, electron transport layers, electron injection layers, photoabsorption layers, or any combination thereof. Organic electroluminescent devices in accordance with this disclosure may also include other layers such as, but not limited to, one or more of a substrate layer, an abrasion resistant layer, an adhesion layer, a chemically resistant layer, a photoluminescent layer, a radiation-absorbing layer, a radiation reflective layer, a barrier layer, a planarizing layer, optical diffusing layer, and combinations thereof. These possible layers are all different from the selectively absorbing brightness enhancing layer of the present disclosure.

In accordance with embodiments of the disclosure, a “brightness enhancing layer” generally refers to a layer which is configured to perform at least one of the following functions upon light emitted from the solid state light source: enhance brightness, extract light, increase luminance, or combinations thereof A brightness enhancing layer may comprise structured patterning, ridges, microlenses, prisms, microstructures (e.g., microspheres) or nanostructures; or the like. In some embodiments, a brightness enhancing layer may comprise a brightness enhancing film, an outcoupling film, a light extraction film, a luminance enhancing film, a light extraction film, or combinations thereof or the like. The person of ordinary skill in the art would recognize that there may be significant overlap among these latter types of films. Many such brightness enhancing films (BEF) are known and commercially available, and may be inventively modified in accordance with this disclosure to provide a “selectively absorbing brightness enhancing layer”. Some BEF function by refracting wavelengths at certain allowed angles while internally reflecting wavelengths at the other angles. The reflected wavelengths are recycled until they exit at the allowed angles and the recycling increases the intensity of the wavelengths at the allowed angles.

Some brightness enhancing films which may be modified in accordance with this disclosure include some commercially available BEF such as Kimoto 100 DX2; Kimoto PBU; Kimoto NSH; Kimoto STE3; or 3M VIKUITI™; or 3M BEF II 90/50; or the like. For example BEF II 90/50 is made up of a 127 micron polyester substrate and a 23 micron prismatic structure. The prismatic structure consists of parallel V-shaped grooves with an apex angle of 90. Other suitable BEF may include films comprising PET (polyethylene terephthalate) film embedded with tightly packed silica nanoballs, of size about 500 to about 1000 nm.

In some embodiments, the selectively absorbing brightness enhancing layer may comprise a composite of at least one brightness enhancing film and at least one light diffusing film. For example, the selectively absorbing brightness enhancing layer may comprise a composite in which a brightness enhancing film is sandwiched between plural light diffusing films. In some embodiments, the illumination system may comprise a plurality of brightness enhancing layers, at least one of which is a selectively absorbing brightness enhancing layer. In some embodiments, the illumination system may comprise a plurality of brightness enhancing layers which are stacked/arranged in a manner such that structured (e.g. prismatic) surfaces thereof are substantially perpendicular to one another.

To facilitate the enhancement of light brightness from an illumination system, it may be useful to configure such system so that a selectively absorbing brightness enhancing layer is adjacent to air, so as to enable outcoupling of light into the ambient environment. Often, a solid state light source of an illumination system may comprise a substrate (e.g., glass or plastic), wherein the selectively absorbing brightness enhancing layer may be disposed on the substrate, and wherein the selectively absorbing brightness enhancing layer may have a refractive index which is configured to increase light extraction from/through the substrate. As a general matter, a selectively absorbing brightness enhancing layer is capable of increasing the lumen output of the illumination system; lumen output may be increased by about 10% to about 40% relative to the same system without the selectively absorbing brightness enhancing layer. Of course, as would be understood, while a selectively absorbing brightness enhancing layer is effective to enhance brightness, extract light, and/or increase luminance, it may also have other light-affecting functions, such as scattering and/or polarizing light.

In accordance with embodiments of the disclosure, a “selectively absorbing brightness enhancing layer” generally refers to a brightness enhancing layer which is configured to absorb light in a selected region of the visible light spectrum. For example, a selectively absorbing brightness enhancing layer may be configured to absorb light in one selected region of the visible light spectrum and optionally have low absorbance or even substantially zero absorbance in other regions of the visible light spectrum; that is, it may transmit substantially all visible light outside the selected region. In certain embodiments, a selectively absorbing brightness enhancing layer may have significant (e.g., from about 10% to about 100%) absorbance in one selected region of the visible light spectrum, and simultaneously have low (e.g., less than about 10%) absorbance outside of the selected region. Nevertheless, there are embodiments within the disclosure in which the illumination system has a color-neutral appearance when not energized, even when viewed through the selectively absorbing brightness enhancing layer.

In some embodiments, the selected region of the visible spectrum may be a green region. In other embodiments, the selected region may be a red region, or a red-orange region. In still other embodiments, the selected region may be a yellow region, i.e., of wavelength from about 560 nm to about 620 nm, more particularly, from about 560 nm to about 590 nm.

In accordance with certain embodiments, the selectively absorbing brightness enhancing layer may be configured to absorb from about 10% to about 90% of light transmitted therethrough in the wavelength range of from about 560 to about 590 nm, while absorbing less than 10% of visible light in other wavelengths. Such an absorbance pattern may enhance red-green color contrast.

Typically, a selectively absorbing brightness enhancing layer comprises a film, such as a thermoplastic film or thermoset material or combinations thereof. In some embodiments, such film may comprise a resin such as polyester (e.g., PET) and/or polyacrylate (e.g., PMMA) and/or PEN; or the like.

In general, a selectively absorbing brightness enhancing layer in accordance with this disclosure comprises a film comprising (e.g., doped with) a selectively absorbing material. The selectively absorbing material may comprise a dye or a pigment. The selectively absorbing material may comprise an inorganic material, an organic material, or combinations thereof. In certain embodiments, the selectively absorbing material comprises a metal compound. A metal compound for use in accordance with this disclosure may comprise an oxide of a metal (e.g., iron oxide, neodymium oxide) or a salt of a metal (e.g., metal halide such as neodymium chloride, or organic metal salt such as neodymium tris-octanoate). In certain embodiments, the metal compound may comprise at least one compound of a rare earth element. For example, the rare earth element may comprise Nd, Dy, Pr, or combinations thereof; or the like. In certain embodiments, the metal compound may comprise a neodymium oxide, a dysprosium oxide, a praseodymium oxide, or combinations thereof; or the like.

In other embodiments, the metal compound may comprise at least one compound of a transition metal element. For example, the transition metal element may comprise Fe, Ni, Co, Cr, Ti, Zr, Zn, or combinations thereof; or the like. The metal compound may comprise an iron oxide, a nickel oxide, a cobalt oxide, a chromium oxide, or combinations thereof; or the like. It is understood that “an iron oxide”, or any metal oxide in this disclosure include rare earth metal oxide, generally refers to a compound of at least that metal and oxygen, but other elements may or may not be present. Thus, a compound such as lithium niobium oxide may be considers as both “a lithium oxide” and “a niobium oxide”. The selectively absorbing material may be other oxygen-containing compounds of transition metals. For example, aqueous solutions of: Co(NO₃)₂ (red); K₂Cr₂O₇ (orange); K₂CrO₄ (yellow); NiCl₂ (turquoise); CuSO₄ (blue); KMnO₄ (purple) can be blended into a resin film (e.g., plastic sheet) to give selective absorption.

In some embodiments, the selectively absorbing material may be a mixture of substances, some of which may selectively absorb in the visible spectrum and some of which do not. For example, a selectively absorbing material may comprise a mixture of rare earth oxides (such as neodymium oxide and/or praseodymium oxide), with non-selective materials such as other metal oxides, e.g., alumina and/or silica, or phosphate/aluminate transparent glassy materials.

Typically, in embodiments, a selectively absorbing brightness enhancing layer may comprise a film which comprises the selectively absorbing material diffused (often, substantially homogeneously diffused) into at least one region of the film. Generally, a selectively absorbing material may be chosen such that it substantially does not itself reflect or refract light, e.g., under light emitted from the solid state light source. Also, a selectively absorbing material may be chosen such that it substantially does not luminesce under light, e.g., under light emitted from the solid state light source.

In some embodiments, the selectively absorbing brightness enhancing layer may comprise a film which is at least partially coated with a selectively absorbing layer of a metal compound. The layer of a metal compound may have a thickness below about 100 nm, preferably below about 10 nm. In other embodiments (not mutually exclusive with the foregoing), the selectively absorbing brightness enhancing layer may comprise particles configured to enhance light extraction. Such particles may comprise an average size of from about 100 nm to about 10000 nm, typically from about 1 micron to about 50 micron. Such particles may be characterized as being one or more of microprisms, microspheres, microlenses, micropyramids, microlenses, photonic crystals, optical fibers, microstructures, nanostructures, volumetric scattering particles, or aerogels; or the like. It would be recognized by the person of ordinary skill that these characterizations may be overlapping; thus, a microsphere particle may act as a microprism in certain embodiments, for example. In certain embodiments, such particles may be disposed on a surface of film and/or within a film. For example, such particles may be disposed on one side of a film. In a specific embodiment, particles which are configured to enhance light extraction may be doped with a selectively absorbing material, e.g., substantially spherical micron-sized silica particles doped with neodymium oxide.

In accordance with embodiments of the invention, the solid state light source may comprise at least one flexible light emitting element. As used herein, flexible may refer to elements which capable of being bent into a shape having a radius of curvature of less than about 10 cm. Typically the at least one flexible light emitting element may comprise an organic electroluminescent device, such as one or more selected from bottom emitting OLED, a top emitting OLED, stacked OLEDS, tandem OLED, phosphorescent OLED, or fluorescence-doped OLED, or combinations thereof (e.g., both top and bottom). As would be understood, an organic electroluminescent device generally comprises at least an anode, a cathode, and an emissive stack (wherein such emissive stack usually comprises at least one electroluminescent material, as well as optionally other materials such as hole transporting agents, hole blocking agents, electron transporting agents, electron blocking agents, etc.). To facilitate light extraction, at least one of the anode or the cathode is generally substantially transparent. In such cases, the selectively absorbing brightness enhancing layer may extract light (as well as enhance its brightness) which is emitted through a substantially transparent anode or substantially transparent cathode.

In many embodiments, the organic electroluminescent device may be encapsulated within at least one barrier to resist oxygen and/or moisture. Such barrier may be a hermetic barrier, and may comprise a multilayer barrier. Such barrier may be preferably substantially transparent so as to allow egress for light emitted from the solid state light source. Where a barrier is employed with an organic electroluminescent device, they are generally configured to form an electronic package, preferably a hermetic electronic package. Of course, means for delivering current to the at least one electroluminescent device, such as vias or pass-throughs or wireless electricity delivery, will be present in any electronic package so as to energize the device.

In typical embodiments of the disclosure, a package may be provided with the selectively absorbing brightness enhancing layer on the outside thereof, e.g., on an outer surface of the package. The layer may generally extract light emitted from the package through the barrier. As will be discussed in greater detail below, one possible advantage of this embodiment may be to allow one to change a light parameter of a pre-packaged solid state light source. That is, a solid state light source (e.g., OLED) may be in the form of a hermetic package; and, to adjust a light parameter of its emitted light (e.g., color temperature, first chromaticity, and/or color contrast parameter), one may optically couple a selectively absorbing brightness enhancing layer to the package. This may avoid having to change the chemistry and/or construction of the solid state light source in order to change its light parameter. This suggests immediate opportunities to simplify manufacturing or after-market adjustment of an already-hermetically-packaged solid state light source.

A solid state light source which may comprise at least one flexible light emitting element typically comprises a plurality of flexible light emitting elements. In such embodiments, the plurality of flexible light emitting elements may be paneled and/or arrayed in strips or stripes, or may be stacked and overlapping, partially overlapping, or nonoverlapping. A plurality of flexible light emitting elements may emit different colors from each other.

Certain embodiments of the disclosure may provide an illumination system comprising a solid state light source which is configured to emit a “total” light (e.g., a combined light, when a plurality of light emitting elements are employed as the solid state light source) which appears white when energized. Emission of light which appears white can be accomplished in several ways. In one configuration, a solid state light source may comprises one or more light emitting elements, wherein at least one (and preferably all) of the light emitting elements is configured to emit light which appears white.

In another configuration, a solid state light source may comprise a plurality of light emitting elements, wherein a total light emitted from the plurality of light emitting elements appears white. Such plurality of light emitting elements may emit at least two different colors, e.g., the plurality of light emitting elements may comprise at least a red-emitting, a blue-emitting, and a green-emitting light emitting element. A total light which appears white is produced by color mixing, as would be understood by persons skilled in the field.

In yet another configuration, the solid state light source may comprises one or more luminescent materials configured to convert light from a light emitting element. Such luminescent material may downconvert and/or upconvert and/or quantum split, and may be chosen from one or more of phosphor or quantum dot; or the like. Such luminescent materials are generally within the barrier layer(s) of an electronic package, in those embodiments where the solid state light source is in the form of an encapsulated package. A solid state light source may emit light which appears white by conversion of light (e.g., blue or UV light) into white light by one or more luminescent materials. Blends of luminescent materials which emit white light, (including some known blends such as triphosphor blends or blends comprising white halo phosphor), may be employed for this utility. Alternatively, another mode of generating white light using luminescent materials comprises color mixing of light emitted from one or more colored light emitting elements (e.g., a blue LED die or blue OLED) and light emitted from one or more phosphor (e.g., a yellow-emitting phosphor). Other combinations are possible, such as a solid state light source comprising a white-light emitting elements, and a plurality of colored light emitting elements which may be combined into a total light which appear white.

An illumination system in accordance with embodiments of this disclosure may comprise a luminaire or fixture configured to facilitate the passage of electrical current to power the solid state light source. Of course, a luminaire or fixture may include many other functions as well, such as affording an ability of directing light, mechanical stability, arranging of arrays of solid state light sources, etc. An illumination system may also optionally comprise other light management devices, such as diffusers, shutters, filters, etc. An illumination system may also optionally comprise environmental packaging, and/or electronic controllers, and/or user management interfaces, and/or switches; or the like.

In many embodiments, an illumination system may be configured as an area lamp (i.e., a lamp which is configured to illuminate an area for general illumination). In some embodiments, an illumination system may also comprise color filters in addition to the selectively absorbing brightness enhancing layer, to further modify or uniformly distribute the color. For example, commercially available PANTONE PLASTICS Color System™ filters are known to allow designers, manufacturers and suppliers who work with plastics to select, specify, and control colors through opaque and transparent plastic color chips in the system. Thus it is also within the scope of this disclosure to optionally employ such filters, especially with OLED light sources.

One specific embodiment of the invention is directed to an illumination system, comprising: an encapsulated, flexible, conformal solid state white light source comprising one or more organic electroluminescent device and at least one barrier layer; and at least one selectively absorbing brightness enhancing film external to the white light source, the selectively absorbing brightness enhancing film capable of modifying at least one of chromaticity, color contrast, or color temperature of light emitted from the white light source. Typically, the solid state white light source may be optically coupled with the at least one selectively absorbing brightness enhancing film on an exterior surface of the source.

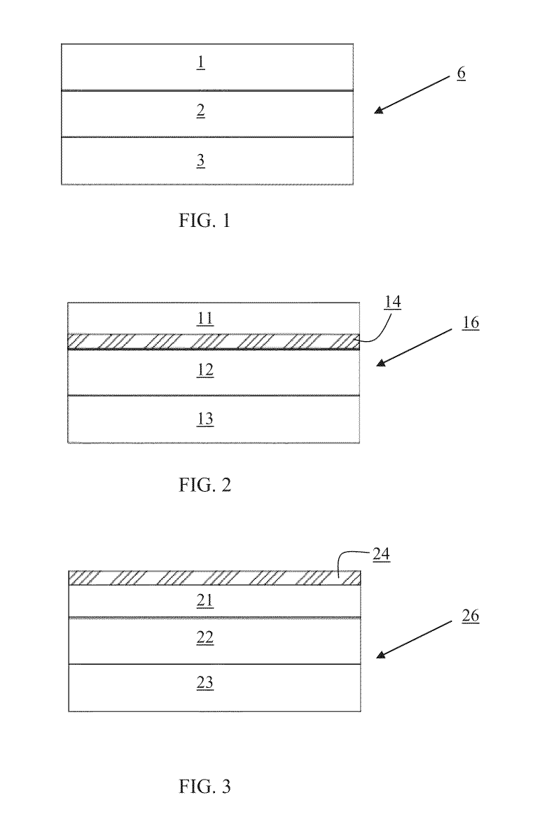

Highly schematized view of embodiments of the invention are depicted in FIG. 1-4. In FIG. 1, item 3 is intended to represent a solid state light source comprising an organic electroluminescent device, which may or may not be encapsulated or packaged. At least one substrate 2, which may be substantially transparent glass and/or plastic, acts as a surface of light egress to which selectively absorbing brightness enhancing layer 1 is affixed, to form illumination system 6. In FIG. 2, item 13 represents essentially the same kind of solid state light source as item 3, and item 12 represents the same kind of substrate as item 2. Layer 11 represents a selectively absorbing brightness enhancing layer having structured patterning 14 on a side nearest a substrate 12. In total, illumination system 16 is provided by FIG. 2. In FIG. 3 is depicted a similar illumination system as in FIG. 2, but structured patterning 24 is on a side of brightness enhancing layer 21 adjacent to the ambient environment. Layer 21 is affixed to a substrate 22 which supports solid state light source 23, to form illumination system 26.

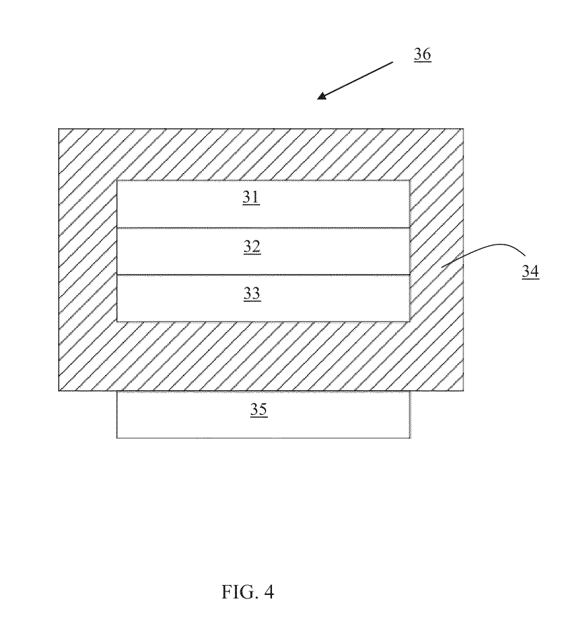

In FIG. 4, an illumination system 36 comprises a hermetic barrier 34 which forms a package including an organic electroluminescent device comprising electrode 31, emissive stack 32, and transparent electrode 33. Selectively absorbing brightness enhancing layer 35 is optically coupled to the organic electroluminescent device, either as-manufactured or post-manufacture.

Certain advantageous methods are provided in the present disclosure, including a method comprising optically coupling a solid state light source with a selectively absorbing brightness enhancing layer. The solid state light source and the selectively absorbing brightness enhancing layer may be any of the previously described sources and layers. In this method, the solid state light source is configured to emit light (e.g., white light) when energized, the light comprising a first color temperature, a first chromaticity, and a first color contrast parameter. Thus, such method may modify at least one of: first color temperature, first chromaticity, or first color contrast parameter.

For example, optically coupling the source with a selectively absorbing brightness enhancing layer may modify at least the color contrast parameter of the solid state light source. As would be understood, “color contrast” typically refers to an ability to distinguish object color under illumination. For example, “red-green color contrast” is an example of the kind of color contrast referred to in this disclosure; in this method, a selectively absorbing brightness enhancing layer may enhance or increase the red-green color contrast of a solid state light source. More particularly, in this method a selectively absorbing brightness enhancing layer may be capable of imparting color contrast values to the light emitted by the solid state light source, which values conform to the CQS (NIST Color Quality System) parameters set forth in Paragraphs [0039], [0040], or of US Patent Publication 2009/0122530, which is hereby incorporated by reference in its entirety as if set forth fully herein.

In some embodiments of this method, a selectively absorbing brightness enhancing layer may decrease a “dCCY” of the solid state light source, where dCCY is the difference in chromaticity of the color point on the Y axis relative to the standard blackbody curve. In some embodiments of this method, the selectively absorbing brightness enhancing layer may be capable of increasing the color temperature of the light emitted from a solid state light source by at least about 50 K (preferably, by at least about 200 K), e.g., from 50 K to 400 K.

As previously described in reference to the illumination system above, a solid state light source in accordance with method embodiments may comprise at least one flexible light emitting element, such as an organic electroluminescent device, which may be any of the devices described above. The organic electroluminescent device may be encapsulated with an barrier (e.g., a hermetic barrier, such as a hermetic multilayer barrier at least a portion of which is substantially transparent) to form a package (e.g., a hermetic package). The selectively absorbing brightness enhancing layer may be placed outside the package to brighten and modify light emitted from the package through the barrier.

In accordance with certain embodiments of this method, the step of optically coupling a solid state light source with a selectively absorbing brightness enhancing layer may comprise at least a step of adhering a substrate of solid state light source (e.g., a packaged, hermetic, or encapsulated solid state light source) with a selectively absorbing brightness enhancing layer via a optical adhesive layer, such as an optical laminating tape. Many such optical laminating tapes are known and commercially available.

Another advantageous method embodiment of the present disclosure is directed to: a method of changing a chromaticity of a flexible organic electroluminescent white light source, which method comprises optically coupling a selectively absorbing brightness enhancing film and a flexible organic electroluminescent white light source.

Applicants of the present invention have learned that color change and color control may be an issue for flexible OLED. It has been found that white OLED devices which employ multiple differently colored electroluminescent elements, sometimes suffer from a shift from their original white color over time. This may be due to the elements of one color (e.g., blue) undergoing degradation at a different rate from the other color emissions from the other EL units. Therefore, it may be difficult for the prior art tandem white OLED device to maintain the initial white color. Color shift has been mitigated by chemical means, making longer lasting OLED materials. But it may be expensive to always use organic electroluminescent materials that offer long-lived color.

This method embodiment is intended to correct this problem; the method may change the chromaticity back to a color point of the flexible organic electroluminescent white light source prior to degradation. Thus, rather than replacing an entire illumination system (e.g., OLED area lamp comprising at least one hermetic/encapsulated/barrier coated package) which has suffered a color point “drift”, one may simply replace a typical prior art brightness enhancing film (if present) with a selectively absorbing brightness enhancing layer, or affix a selectively absorbing brightness enhancing layer.

Some embodiments of the invention provide a method (e.g., a manufacturing method) of making a selectively absorbing brightness enhancing film, which method comprises at least a step of doping a film with a selectively absorbing material. The step of doping can be accomplished prior to the film being made into “brightness enhancing” form, or subsequent thereto.

Thus, a manufacturing method may comprise doping a selectively absorbing material (i.e., any of the selectively absorbing materials previously described) into a film (e.g., a thermoplastic or thermoset resin film), followed by a subsequent step of adding (e.g., affixing, embedding, sputtering, forming) particles or structured patterning configured to enhance light extraction. Alternatively, a manufacturing method may further comprise a prior step of adding particles or structured patterning configured to enhance light extraction, to a film. In yet another alternative, a film may be made into a selectively absorbing brightness enhancing layer by doping a film with a selectively absorbing material in the form of doped brightness enhancing particles, silica microspheres doped with a rare earth oxide. This latter method can serve to impart selective absorbing character and brightness enhancing character to a film at the same time. In yet a further alternative, a manufacturing method may comprise receiving a film which is already a brightness enhancing film and then doping that film with a selectively absorbing material.

In some embodiments, “doping” may comprise depositing a selectively absorbing material on at least one surface of a brightness enhancing film. A depositing step may deposit a layer of selectively absorbing material on at least one of a smooth side or a structured surface of a brightness enhancing film. In some embodiments, depositing comprises vapor deposition of the selectively absorbing material. For example, vapor deposition may comprise sputtering or thermally vaporizing the selectively absorbing material onto a brightness enhancing film held under nondestructive conditions. In some embodiments, depositing onto a film comprises depositing a layer of selectively absorbing material comprising an average thickness of from about 2 nm to about 10 nm. Alternatively, “doping” may comprise combining a thermoplastic material and a selectively absorbing material under conditions in which the thermoplastic material is at least partially melted, and then forming a film from the blend, then patterning light enhancing structures into the film. In any case, doping may be conducted under conditions effective to diffuse (e.g., homogeneously diffuse) the selectively absorbing material into at least one region of the film.

The selectively absorbing material may be applied to a brightness enhancing layer by melting the selectively absorbing material and forming a thin film on a brightness enhancing layer, or by vacuum-depositing a thin film onto a brightness enhancing layer. Some suitable vacuum deposition methods may include on or more of e-beam evaporation, sputtering evaporation, other physical vapor deposition (PVD), thermal evaporation, laser molecular beam epitaxy (LMBE), pulsed laser deposition (PLD), or combinations thereof; or the like. These methods are not necessarily mutually exclusive.

In order to promote a further understanding of the invention, the following examples are provided. These examples are illustrative, and should not be construed to be any sort of limitation on the scope of the claimed invention.

### EXAMPLES

In a sputtering chamber, neodymium oxide was placed in a crucible. A commercial outcoupling (OCF) film (sourced from 3M Corporation and based on a nanostructured polyethyleneterephthalate) was placed at a position approximated 30 cm distant from the crucible. Neodymium oxide was then thermally and evaporatively sputtered under vacuum onto the film on a side which was not nanostructured. The target was kept far enough away so that it did not melt. An amount of about 3 parts by weight neodymium oxide per 100 parts by weight of OCF film, was deposited, to form a metal compound layer of thickness in a range of from 2 nm-10 nm. After sputtering was complete, the film was brought to a temperature approaching its melting point, so as to anneal the film and thus diffuse the neodymium oxide into the film. Separately, an OLED device was assembled as a hermetic package, in which a transparent electrode was adjacent a transparent barrier film encapsulating the package. The selectively absorbing brightness enhancing film as prepared above was then coupled adjacent the package, with the structured side of the OCF was adjacent the barrier layer, to provide an exemplative illumination system.

The comparative colorimetric result of the OLED device without the inventive OCF from the example above, as compared to the exemplative illumination system, is shown in Table I below.

TABLE I
Control (OLED without OCF)

| | |
|---|---|
| ccx | 0.428 |
| ccy | 0.411 |
| CCT (K) | 3203 |
| lumen output | 20 |

Example (OLED with inventive OCF)

| | |
|---|---|
| ccx | 0.398 |
| ccy | 0.377 |
| CCT (K) | 3547 |
| lumen output | 22 |

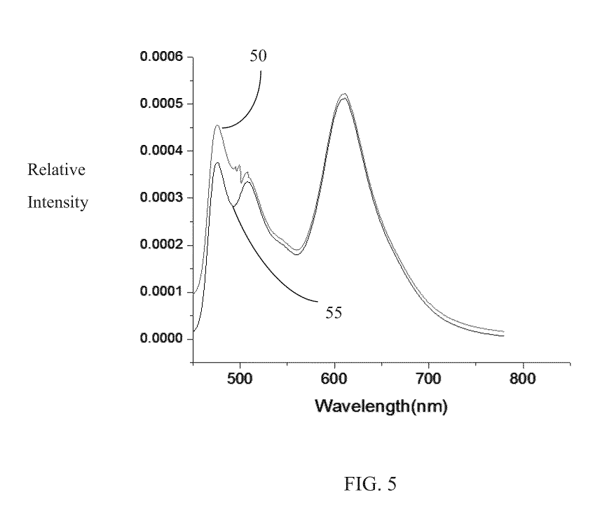

As can be seen in Table I, the selectively absorbing brightness enhancing film of the Example increased the correlated color temperature (CCT) by more than 300 K, and decreased the ccy value of the chromaticity coordinates. Despite the presence of a selectively absorbing material in the film, the lumen value of light emitted from the OLED package was still increased. The emission spectrum of the illumination system is shown in FIG. 5. Trace 55 is the emission spectrum of the OLED device without the inventive OCF, and trace 50 is the emission spectrum of the exemplative illumination system. A selective enhancement of blue color in the spectrum is apparent.

As used herein, approximating language may be applied to modify any quantitative representation that may vary without resulting in a change in the basic function to which it is related. Accordingly, a value modified by a term or terms, such as “about” and “substantially,” may not be limited to the precise value specified, in some cases. The modifier “about” used in connection with a quantity is inclusive of the stated value and has the meaning dictated by the context (for example, includes the degree of error associated with the measurement of the particular quantity). “Optional” or “optionally” means that the subsequently described event or circumstance may or may not occur, or that the subsequently identified material may or may not be present, and that the description includes instances where the event or circumstance occurs or where the material is present, and instances where the event or circumstance does not occur or the material is not present. The singular forms “a”, “an” and “the” include plural referents unless the context clearly dictates otherwise. All ranges disclosed herein are inclusive of the recited endpoint and independently combinable.

As used herein, the phrases “adapted to,” “configured to,” and the like refer to elements that are sized, arranged or manufactured to form a specified structure or to achieve a specified result. While the invention has been described in detail in connection with only a limited number of embodiments, it should be readily understood that the invention is not limited to such disclosed embodiments. Rather, the invention can be modified to incorporate any number of variations, alterations, substitutions or equivalent arrangements not heretofore described, but which are commensurate with the spirit and scope of the invention. Additionally, while various embodiments of the invention have been described, it is to be understood that aspects of the invention may include only some of the described embodiments. Accordingly, the invention is not to be seen as limited by the foregoing description, but is only limited by the scope of the appended claims. It is also anticipated that advances in science and technology will make equivalents and substitutions possible that are not now contemplated by reason of the imprecision of language and these variations should also be construed where possible to be covered by the appended claims.

What is claimed as new and desired to be protected by Letters Patent of the United States is:

1. An illumination system comprising a solid state light source optically coupled with a selectively absorbing brightness enhancing layer.

2. The system in accordance with claim 1, wherein the solid state light source is configured to emit light when energized comprising a first color temperature, a first chromaticity, and a first color contrast parameter, and wherein the selectively absorbing brightness enhancing layer is capable of modifying at least one of the first color temperature, the first chromaticity, or the first color contrast parameter of the solid state light source.

3. The system in accordance with claim 1, wherein the selectively absorbing brightness enhancing layer is capable of one or more of:
increasing a color temperature of the solid state light source by at least about 50 K;
decreasing a dCCY of the solid state light source; and
increasing a red-green color contrast of light emitted by the solid state light source.

4. The system in accordance with claim 1, wherein the solid state light source comprises at least one flexible light emitting element comprising an organic electroluminescent device.

5. The system in accordance with claim 4, wherein the organic electroluminescent device is encapsulated with at least one barrier to form a package, and wherein the selectively absorbing brightness enhancing layer is outside the package and extracts light emitted from the package through the at least one barrier.

6. The system in accordance with claim 1, wherein the solid state light source is configured to emit a total light when energized which appears white.

7. The system in accordance with claim 1, wherein the selectively absorbing brightness enhancing layer comprises a film doped with a selectively absorbing material.

8. The system in accordance with claim 7, wherein the selectively absorbing material comprises at least one compound of a rare earth element.

9. The system in accordance with claim 1, wherein the selectively absorbing brightness enhancing layer is configured to absorb light in one selected region of the visible light spectrum and to transmit substantially all visible light outside the selected region.

10. The system in accordance with claim 9, wherein the selectively absorbing brightness enhancing layer is configured to selectively absorb light in a wavelength range of from about 560 nm about 620 nm.

11. The system in accordance with claim 1, wherein the selectively absorbing brightness enhancing layer comprises particles configured to enhance light extraction.

12. The system in accordance with claim 11, wherein the particles comprise a selectively absorbing material comprising at least one compound of a rare earth element.

13. An illumination system, comprising:
an encapsulated, flexible, conformal solid state white light source comprising one or more organic electroluminescent device and at least one barrier layer; and
at least one selectively absorbing brightness enhancing film external to said white light source, the selectively absorbing brightness enhancing film capable of modifying at least one of chromaticity, color contrast, or color temperature of light emitted from said white light source.

14. The system in accordance with claim 13, wherein said encapsulated source is optically coupled with the at least one selectively absorbing brightness enhancing film on an exterior surface of said encapsulated source.

15. Method comprising optically coupling a solid state light source with a selectively absorbing brightness enhancing layer.

16. The method in accordance with claim 15, wherein the solid state light source is configured to emit light when energized, the light comprising a first color temperature, a first chromaticity, and a first color contrast parameter, and wherein the selectively absorbing brightness enhancing layer modifies at least one of the first color temperature, the first chromaticity, or the first color contrast parameter of the solid state light source.

17. Method of changing a chromaticity of a flexible organic electroluminescent white light source, the method comprising optically coupling a selectively absorbing brightness enhancing film and a flexible organic electroluminescent white light source.

18. The method in accordance with claim 17, wherein the flexible organic electroluminescent white light source has undergone a change in color point of its emitted light due to a degradation.

19. Method of making a selectively absorbing brightness enhancing film, the method comprising at least a step of doping a film with a selectively absorbing material.

20. The method in accordance with claim 19, wherein doping comprises depositing the selectively absorbing material on at least one surface of a brightness enhancing film.

21. The method in accordance with claim 20, wherein depositing comprises sputtering or thermally vaporizing a rare earth compound onto the brightness enhancing film.
